(19) United States
(12) Patent Application Publication
(10) Pub. No.: US 2024/0220688 A1
(43) Pub. Date: Jul. 4, 2024

(54) Numerical Simulation Method By Deep Learning And Associated Recurrent Neural Network

(71) Applicant: ANSYS, Inc., Canonsburg, PA (US)

(72) Inventors: Thibaut MUNZER, Paris (FR); Jocelyn Ahmed MAZARI, Paris (FR); Louis VERRET, Sevres (FR); Pierre YSER, Paris (FR)

(21) Appl. No.: 18/412,238

(22) Filed: Jan. 12, 2024

Related U.S. Application Data
(63) Continuation of application No. PCT/FR2021/051461, filed on Aug. 11, 2021.

(51) Int. Cl. G06F 30/28

(52) U.S. Cl. CPC G06F 30/28

(57) ABSTRACT

A computer-implemented numerical simulation method (500) for predicting the flow of a fluid in a simulation domain by a deep learning model, comprising a step (510) of generating a mesh of the domain and, for each node i of the mesh, a step (520) of creating a position vector pi and an attribute vector Xi at a first iteration t; a step (530) of computing messages between the node i and all its neighbouring nodes by means of a recurrent artificial neural network (100); a step (540) of updating the attribute vector by means of said network, from the computed messages, giving a state of the attribute vector at a second iteration t+1; the sequence comprising the step (530) of computing messages and the step (540) of updating the attribute vector being carried out by applying a local operator and being repeated n times until a convergence is obtained, said method finally comprising a step (550) of interpreting the attribute vectors of all the nodes of the mesh as a physical field such as a velocity field or a pressure field.

### PRIORITY

This application claims the priority of and is a continuation of Patent Cooperation Treaty App. No. PCT/FR2021/051461, filed Aug. 11, 2021, titled “Numerical Simulation Method by Deep Learning and Associated Recurrent Neural Network,” the entire disclosure of which is hereby incorporated by reference herein.

### TECHNICAL FIELD

The present invention pertains to the field of numerical simulation, particularly the numerical simulation of complex physical phenomena such as fluid flows.

More specifically, the present invention relates to a numerical simulation method using deep learning and a recurrent neural network (RNN) model for the implementation of this method.

The present invention has a direct, but not limited, application in the design of aerodynamic profiles such as aircraft wing profiles.

### BACKGROUND OF THE INVENTION

Numerical simulation and machine learning (Machine Learning) share the common goal of predicting the behavior of a system through data analysis and mathematical modeling.

As such, these two techniques can be combined in a hybrid approach, driven by applications partly governed by causal relationships, to facilitate a more intelligent and efficient data analysis.

The research focusing on such a combination can generally be divided into two groups based on the adopted perspective: that of numerical simulation or that of machine learning. Here, we are only interested in the first group, as it concerns the integration of machine learning techniques into numerical simulation, often for a specific application such as fluid flow simulation. An example is described in Tompson, J., Schlachter, K., Sprechmann, P., Perlin, K.: Accelerating Eulerian fluid simulation with convolutional networks. In: ICML (2017).

In the field of fluid mechanics, one of the advantages of a numerical simulation using machine learning is to replace the traditionally expensive Computational Fluid Dynamics (CFD) methods while maintaining sufficient accuracy for the targeted industrial applications, at least in certain phases of development. The machine learning models used in numerical simulation allow either for the spatial propagation of information in the domain through the mesh using locally informed neural networks or for parallel computations by decomposing the domain. In both cases, these are calculations using Schwarz methods.

The second case is exemplified in Li, Ke et al. (2019). D3M: A deep domain decomposition method for partial differential equations which describes a deep learning-based variational solver using a domain decomposition method, to implement parallel computations in physical subdomains. This method is a straightforward application of iterative Schwarz methods where each local prediction is made by a deep learning algorithm.

This method is based on parallel local predictions and does not rely on spatial information propagation, let alone nearest neighbor propagation.

In a mesh, information propagation can be enhanced by the interconnection that exists between nodes, akin to that found in a graph.

Indeed, in a graph, all data points (nodes) are interconnected with each other and no longer have a regular structure. This means that the data are no longer independent and regularly distributed, making most standard machine learning models inappropriate, as their derivations rely heavily on these assumptions (such as CNNs, Convolutional Neural Networks). To overcome this problem, it is possible to extract numerical data from graphs and use models that operate directly on this type of structured data.

However, the use of deep learning models on graphs is known and has given rise to specific neural networks called GNNs (Graph Neural Networks).

GNNs are particularly suited as message-passing algorithms.

This type of architecture is especially popular in chemistry to help predict the properties of molecules, as described in the document WO2020186109A2.

Some models have a common feature of message passing through the nodes of the graph. This has led to defining a general framework of so-called MPNNs (Message Passing Neural Networks). An example is described in Justin Gilmer, Samuel S Schoenholz, Patrick F Riley, Oriol Vinyals and George E Dahl, “Neural message passing for quantum chemistry”, ICML, 2017.

To the applicant's knowledge, no solution proposes using a recurrent network to spatially propagate information, without temporal considerations, in a numerical simulation domain by treating the mesh as a graph.

### OBJECT AND SUMMARY OF THE INVENTION

The present invention introduces a novel approach for conducting numerical simulations assisted by deep learning, treating meshes as graphs in which all nodes are interconnected and thus facilitate spatial and stationary propagation of information.

To this end, the present invention aims at a numerical simulation method, implemented by computer, to predict the flow of a fluid in a simulation domain using a deep learning model. This includes a step of generating a mesh of the domain comprising a plurality of nodes, and is remarkable in that it includes for each node i of the mesh:
a step of creating a position vector pᵢ and an attribute vector xᵢ at a first iteration t (which can represent a temporal step, or a step of spatial information propagation);
a step of calculating messages mᵢⱼ between node i and all its neighboring nodes by a recurrent artificial neural network;
a step of updating the attribute vector by said network, based on the calculated messages, giving a state of the attribute vector at a second iteration t+1;

The sequence, including the step of calculating messages and the step of updating the attribute vector, is carried out by the application of a local operator and iterated n times until convergence, and said method finally includes:
a step of interpreting the attribute vectors of all the nodes of the mesh as a physical field such as a velocity field or a pressure field.

This treatment of the mesh nodes according to a graph representation solves the problem of mapping high-dimensional objects into simple vectors through local aggregation steps to perform machine learning tasks such as regression or classification.

Thus, the present invention proposes to use an RNN network implementing a specific model (GNN or other) so that it learns to converge to a fixed point, solely from an initial solution and a final solution without intermediate examples. This represents a fundamental difference from classical temporal RNN networks in which examples are available for each temporal iteration. In other words, in the method of the invention, the network learns to converge from an initial point to a final point. Advantageously, the recurrent neural network can represent only a spatial operator and is not trained on intermediate solutions of convergence to a spatial fixed point. According to an aspect of the invention, the calculation of a message mᵢⱼ between a node i and a neighboring node j, at iteration t, is done with a message function of the network:

$${m}_{ij}^{t} = message ( {x}_{i}^{t} , {x}_{j}^{t} , {e}_{ij}^{t} )$$

eᵢⱼ being an attribute of the edge connecting nodes i and j.

Advantageously, this attribute is a distance according to the formula:

$${e}_{ij}^{t} = {p}_{i}^{t} - {p}_{j}^{t}$$

In accordance with one embodiment of the invention, the update of the attribute vector of a node i is performed using a “update” function of the network, following the recurrence formula:

$${x}_{i}^{t + 1} = {x}_{i}^{t} + update ( {x}_{i}^{t} , {mean}_{j ∈ N ( i )} ( {m}_{ij}^{t} ) )$$

In which, “mean” is a function for calculating the average, and N(i) represents the set of neighboring nodes of node i.

Advantageously, the network is trained using stochastic optimization algorithms such as the Adam algorithm and its variations, along with an L2 loss function. The invention also pertains to a recurrent artificial neural network, downloadable from a communication network and/or stored on a microprocessor-readable medium and/or executable by a microprocessor, comprising program code instructions for executing a digital simulation method as described herein.

Advantageously, this network is of the Graph Neural Network (GNN) type, designed to process the simulation domain mesh as a graph. Previously, with conventional networks like convolutional networks, it was challenging to properly handle unstructured graph-type data because the relationships between the data were regularly spatially structured. With GNNs, edges are now added as information to the network in the form of an adjacency table, for example.

The invention also encompasses a non-transitory storage medium readable by a terminal, storing a computer program comprising a set of instructions executable by a computer or processor to implement a digital simulation method as described. The fundamental concepts of the invention have been outlined above in their most basic form. Further details and features will become clearer upon reading the following description and considering the appended drawings, which provide a non-limiting example of an embodiment of a deep learning simulation method following the principles of the invention.

### BRIEF DESCRIPTION OF THE FIGURES

The figures are provided purely as an illustration for comprehension of the invention and do not limit the scope thereof. The different elements are represented schematically. n all of the figures, identical or equivalent elements are designated by the same reference sign.

It is thus illustrated, in:

FIG. 1: an example of a coarse mesh of a simulation domain for predicting air flow around a wing profile;

FIG. 2: a simplified view of the numerical scheme on which the simulation method according to an embodiment of the invention is based;

FIG. 3: iterations obtained on the simulation domain by the recurrent network used;

FIG. 4: a synopsis of the main steps of the simulation method according to the invention;

FIG. 5: an example of iterations obtained on the simulation domain until convergence.

### DETAILED DESCRIPTION OF EMBODIMENTS

It should be noted that some well-known technical elements to those skilled in the art are described here to avoid any insufficiency or ambiguity in understanding the present invention.

In the embodiment described below, reference is made to a numerical simulation method by deep learning primarily intended for predicting air flows around wing profiles. This non-limiting example is given for a better understanding of the invention and does not exclude the implementation of the method for predicting other fluid movements.

Of course, an analogy can be made with other physical phenomena also governed by partial differential equations and involving numerical simulation.

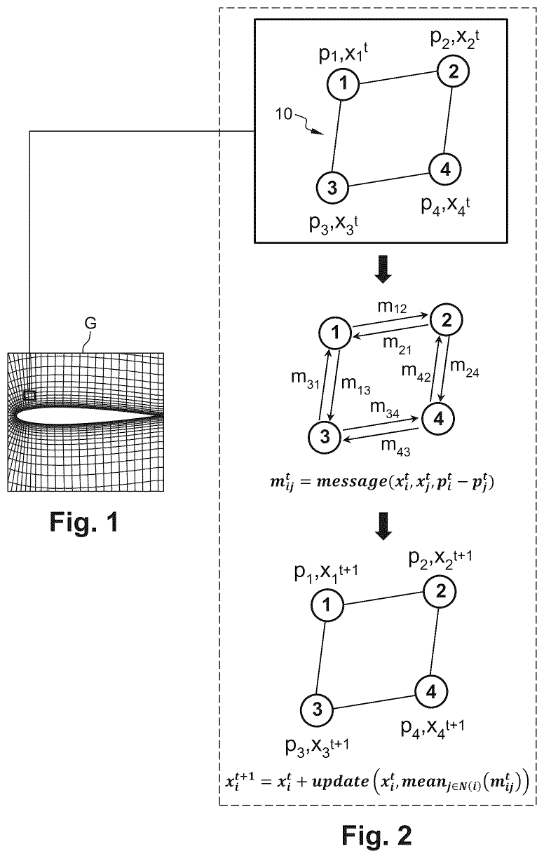

FIG. 1 represents a simulation domain defined around a wing profile of particular geometry. A mesh is created in this domain to calculate fields of variables (such as speed and pressure) around the wing profile, using a finite element method for example.

The nodes and edges of the mesh form a graph G, in the mathematical sense of the term, which can therefore be processed by suitable artificial neural networks such as recurrent networks, especially GNNs (Graph Neural Network). In the rest of the description, the term network, when used alone, refers to an artificial neural network. The terms node and edge, as well as their plurals, are used according to the definitions given to them in graph theory.

For simplification purposes, the numerical scheme operated by the method of the invention will be explained on a restricted part of the graph G comprising, for example, four nodes connected in a quadrilateral (two edges per node and four edges in total). FIG. 2 represents such a part 10 comprising four nodes numbered 1 to 4.

It should be noted that part 10 does not necessarily correspond to a mesh cell but represents a representative sample of the graph G allowing to simply illustrate the basic properties of the complete graph, namely the arrangement of the nodes, the edges between the nodes, the non-orientation, the neighborhood of each node, etc. Moreover, this simplified representation does not exclude the presence of other neighboring nodes. Indeed, according to the mesh represented in FIG. 1, each non-extremal node is surrounded by four neighboring nodes.

Initially and following the scheme of FIG. 2, each node i of the graph is assigned a position vector pᵢ and an attribute vector xᵢ^{t} at iteration t. Unlike attribute vectors, which are variables during iterations, node positions are considered fixed according to a simplified working hypothesis.

Then, for each node i, messages mᵢⱼ^{t} with neighboring nodes j are calculated with a message function of the recurrent network:

$${m}_{ij}^{t} = message ( {x}_{i}^{t} , {x}_{j}^{t} , {p}_{i}^{t} - {p}_{j}^{t} )$$

The difference between the positions of nodes i and j, as an argument of the message function, represents an attribute of the edge connecting said nodes i and j. In the illustrated embodiment, the graph is non-oriented so that between two neighboring nodes i and j, messages are calculated in both directions: mᵢⱼ and mⱼᵢ. The calculation of the messages then allows for the updating of the attribute vectors by recurrence over the time step following the relation:

$${x}_{i}^{t + 1} = {x}_{i}^{t} + update ( {x}_{i}^{t} , {mean}_{j ∈ N ( i )} ( {m}_{ij}^{t} ) )$$

In this relation, update is an update function that takes as arguments the previous state of the attribute vector and an average of the calculated messages, and N(i) is the set of neighboring nodes of node i. The new state of each node depends only on the states of its immediate neighboring nodes. The scheme thus described is repeated until convergence of the attribute vectors is achieved. This results in obtaining a simulation result.

This scheme is implemented by a neural network with a deep learning model. Preferably, the network used is a GNN (Graph Neural Network). Indeed, the mesh of a simulation domain is a graph and can therefore be transposed into a GNN. The GNN allows for spatial propagation of information between the nodes of the mesh, each node collecting information from its neighboring nodes. Moreover, in a mesh, each node can be reached step by step from any node. In other words, the mesh does not contain any isolated node.

The GNN employs methods based on neighborhood information aggregation through a local iterative process.

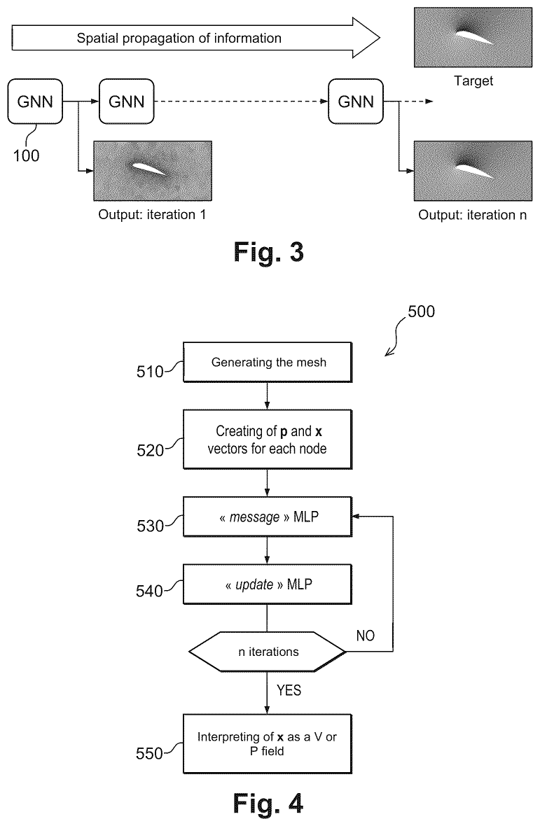

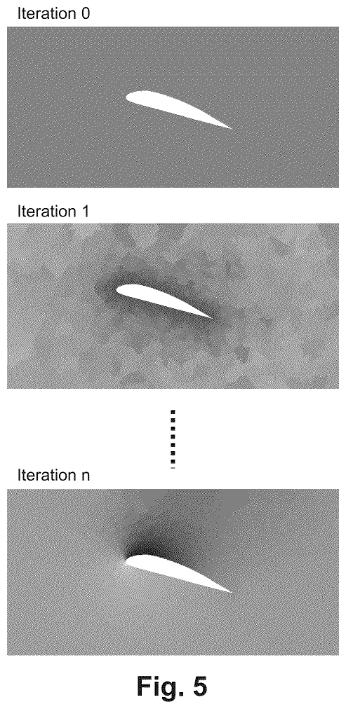

FIG. 3 shows iterations obtained by a recurrent network 100 after training on a simulation domain. This network 100 obtained after training corresponds to a spatial propagation operator. At each iteration n, the network 100 is identically repeated to achieve convergence to the fixed point of the problem.

The advantage of this approach for spatial convergence is having smaller and more generic neural networks in memory. Referring to FIG. 4, the numerical scheme described above is applied in a numerical simulation process 500 implemented by computer comprising:
an initial step 510 of generating a coarse mesh of the simulation domain comprising a plurality of nodes;
a step 520 of creating a position vector p and an attribute vector x for each node of the generated mesh;
for a number n of iterations (n=70, for example), application of the trained recurrent neural network 100 corresponding to:
   a step 530 of calculating messages between neighboring nodes;
   a step 540 of updating the attribute vectors;
a step 550 of interpreting the attribute vectors as a velocity field or a pressure field over the entire mesh;

The steps of the process are implemented by a GNN, which is a neural network model specifically designed to operate on graphs. The input to the network is an undirected graph formed by the nodes and edges of the mesh of the simulation domain, with node attributes and edge attributes.

From this input, the GNN then operates in two phases. The first is a message-passing phase, which propagates information across the graph to construct a neural representation of the entire graph. The second is an interpretation phase in which the neural representation of the graph is used to make predictions.

The message-passing phase includes n steps of information propagation by repeating the neural network. The functions for calculating messages and updating attribute vectors can be trained using stochastic optimization algorithms, such as the Adam algorithm or its variants, and L2 loss functions.

To evaluate the quality of the predictions obtained by the implementation of the simulation process, it is possible to calculate a confidence score as explained below. The confidence score can be constructed on multi-scale criteria, notably with physical coefficients and network coefficients.

### Physical Coefficients (Example: Residue on Volume)

The residue of an equation solved by simulation software is a proxy for knowing the residual error of the solution. This coefficient involves calculating the mean value and standard deviation of the residue over the entirety of the training data set. This will yield a distribution of residues. This distribution resembles a Gaussian if the abscissa is on a logarithmic scale.

The first criterion can then be calculated by considering that if the average residue of the prediction is not in this distribution, the inference is incorrect. Indeed, the network's inference cannot be drastically better or worse than that of the training. This condition corresponds to the following inequality:

$$mean ( {ℛ}_{train} ) - std ( {ℛ}_{train} ) < {ℛ}_{sim} < mean ( {ℛ}_{train} ) + stf ( {ℛ}_{train} )$$

With mean being the arithmetic mean, std being the variance, [symbol] ₜᵣₐᵢₙ the residue on the training database, and [symbol] ₛᵢₘ the residue on the simulation to be studied. The distance from the distribution can be obtained with the Mahalanobis distance:

$${d}_{Res} = \vert \frac{{ℛ}_{sim} - mean ( {ℛ}_{train} )}{std ( {ℛ}_{train} )} \vert$$

### Network Coefficients (Example: Cosine Similarity in Latent Space)

The latent space of networks encodes in a high-dimensional vector the input geometry as well as the boundary conditions (speed, temperature, etc.). One approach to quantifying confidence in the predictions is therefore to measure the proximity between the new vectorization of the input and that of the training geometries using the following cosine similarity metric:

$${C}_{PNS} = {max}_{y ∈ {D}_{train}} \frac{{f ( {y}^{*} )}^{T} f ( y )}{‖ f ( {y}^{*} ) ‖ ‖ f ( y ) ‖}$$

With y* the new input, Dₜᵣₐᵢₙ the training data and f(y) the vectorization associated with y.

### Final Confidence Score

Through a number of test cases ranging from complete noise to a correct test geometry, it has been possible to construct a linear scale setting the worst score at 0 and the best at 1.

Each score of a new prediction (residue, cosine similarity) is always projected onto this scale between 0 and 1. After scaling, the final confidence score is calculated as follows:

$$C = \frac{\frac{1}{m} {\sum }_{i = 0}^{m} {C}_{Phys}^{i} + \frac{1}{n} {\sum }_{j = 0}^{n} {C}_{Net}^{j}}{2}$$

With C_{phys}ⁱ being the i^{th} physical confidence score and C_{Net}^{j} being the j^{th} network confidence score.

In the case of physical residue and a single network:

$$C = \frac{1 - {d}_{Res} + {C}_{cos}}{2}$$

This overall confidence score allows aggregating physical information and feature learning to assist the design engineer in distinguishing between good and bad predictions.

It is clear from this description that certain steps of the simulation process can be completed, modified, replaced, or omitted, and that some adjustments can be made to the used machine learning models, without departing from the scope of the invention. For example, the simulation process can be part of a design process for a technical object such as an airplane wing, allowing the study of fluid flow around said object.

1. A Numerical simulation method, computer-implemented, for predicting the flow of a fluid in a simulation domain by a deep learning model implemented in a computer, said method comprising a step of generating a mesh of the domain and characterized in that it includes for each node i of the mesh:
a step of creating a position vector pᵢ and an attribute vector xᵢ at iteration t;
a step of calculating messages mᵢⱼ between node i and all its neighboring nodes by a recurrent artificial neural network;
a step of updating the attribute vector by said network, based on the calculated messages, giving a state of the attribute vector at iteration t+1;
the sequence including the step of calculating messages and the step of updating the attribute vector being carried out by the application of the same recurrent neural network, interpreted as a local operator, and repeated n times until convergence is achieved, said method finally comprising:
a step of interpreting the attribute vectors of all the nodes of the mesh as a physical field such as a velocity field or a pressure field.

2. The method according to claim 1, in which the calculation of a message mᵢⱼ between a node i and a neighboring node j, at iteration t, is done with a message function of the network:
$${m}_{ij}^{t} = message ( {x}_{i}^{t} , {x}_{j}^{t} , {e}_{ij}^{t} )$$
eᵢⱼ being an attribute of the edge connecting nodes i and j.

3. The method according to claim 2, in which:
$${e}_{ij}^{t} = {p}_{i}^{t} - {p}_{j}^{t}$$

4. The method according to claim 1, in which the updating of the attribute vector of a node i is done with an update function of the network following the recurrence relation:
$${x}_{i}^{t + 1} = {x}_{i}^{t} + update ( {x}_{i}^{t} , {mean}_{j ∈ N ( i )} ( {m}_{ij}^{t} ) )$$
in which mean is a function for calculating the average and N(i) is the set of neighboring nodes of node i.

5. The method according to claim 1, in which the network is trained using stochastic optimization algorithms such as the Adam algorithm and its variants, and an L2 loss function.

6. The method according to claim 1, in which the recurrent neural network represents only a spatial operator and is not trained on intermediate solutions of convergence to a spatial fixed point.

7. A recurrent artificial neural network, downloadable from a communication network and/or stored on a microprocessor-readable medium and/or executable by a microprocessor, characterized in that it comprises program code instructions for executing a numerical simulation method according to claim 1.

8. The recurrent artificial neural network according to claim 7, implementing a GNN (Graph Neural Network) model in order to treat the mesh of the simulation domain as a graph.

9. A non-transitory computer-readable storage medium storing a computer program comprising a set of instructions executable by a computer or processor to implement a numerical simulation method according to claim 1.
